(19) United States
(12) Patent Application Publication
(10) Pub. No.: US 2007/0051470 A1
(43) Pub. Date: Mar. 8, 2007

(54) Plasma processing apparatus and method

(76) Inventors: Takehisa Iwakoshi, Kokubunji (JP); Junichi Tanaka, Hachioji (JP); Hiroyuki Kitsunai, Kokubunji (JP); Toshio Masuda, Hino (JP); Daisuke Shiraishi, Hikari (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/362,024

(22) Filed: Feb. 27, 2006

(30) Foreign Application Priority Data
Sep. 7, 2005 (JP) 2005-259425

(51) Int. Cl. B08B 3/12; B08B 6/00; G06F 19/00; C23C 16/00; C23F 1/00

(52) U.S. Cl. 156/345.28; 134/1; 134/1.1; 700/121; 118/723 R

(57) ABSTRACT

A plasma processing apparatus includes: a processing chamber; a state detector for detecting a state of plasma in the processing chamber; an input unit for inputting process result data of a specimen processed in the plasma processing chamber; and a controller including a prediction equation forming unit for forming a prediction equation of a process result in accordance with plasma state data detected with the state detector for the plasma process simulating a specimen existing state in the processing chamber in a specimen non-placed state and process result data of the specimen input with the input unit and processed by the plasma process in a specimen placed state, and storing the prediction equation, wherein the controller predicts the process result of a succeeding plasma process in accordance with plasma state data newly acquired via the state detector in the specimen non-placed state and the stored prediction equation.

### BACKGROUND OF THE INVENTION

1. Field of the Invention

The present invention relates to plasma processing techniques, and more particularly to plasma processing techniques capable of executing an optimum process by predicting the result of a plasma process.

2. Description of the Related Art

The dimensions of semiconductor devices have become fine year after year. Therefore, requirement for a work precision have become severe. A variation of even several nm or smaller may cause defective devices.

In a plasma processing apparatus for physically and chemically processing semiconductor wafers by decomposing process gasses by plasma, chemical substances and the like generated inside the apparatus are attached to and remain on the inner wall of a plasma processing chamber. This influences the wafer process in many cases. Therefore, even if the process conditions are maintained constant, the process result such as a patterning size changes as the wafer process is repetitively executed, resulting in a problem of difficulty in stable mass production.

In order to deal with this problem, so-called conditioning is performed such as removing chemical substances attached to the inner wall of a processing chamber by generating cleaning plasma in the processing chamber and attaching proper chemical substances to the inner wall. Recently, this conditioning is executed before each wafer is processed, in order to satisfy a requested working precision. This conditioning is executed in the state that no wafers are placed in the processing chamber, in order to reduce non-product wafers (NPW) which are not contributed to production, and to acquire a high throughput. However, use of this approach is insufficient for maintaining wafer process results perfectly constant, and the wafer process results change gradually. It is therefore necessary to perform maintenance before the process results change to an extent that the process results become problematic, such as component replacement by dismounting a plasma processing apparatus and cleaning with liquid or ultrasonic waves. The reasons of variation in wafer process results include various factors such as a change in temperatures of components constituting a processing chamber, in addition to deposition films attached to the inner wall of the chamber.

Some schemes have been proposed under these backgrounds. For example, a change in process state inside a plasma processing apparatus is detected, and the detection results are fed back to the plasma processing apparatus to adjust wafer process conditions and acquire constant process results.

These techniques are known, for example, in JP-A-2002-100611 (corresponding to U.S. Pat. No. 6,590,179) and JP-A-2004-241500 (corresponding U.S. Ser. No. 10/377,824). These techniques propose to monitor an emission spectrum or the like of plasma during wafer processing, to correlate beforehand a change in spectrum with a change in process results, to detect a change in processing, and to properly adjust the process conditions. With this feedback, the techniques propose to realize stable processing.

The state immediately after apparatus maintenance is different from a mass production state during continuous processing of wafers, because there is almost no deposits on the inner wall of a processing chamber after cleaning. Therefore, the wafer processing results change immediately after the maintenance. In order to solve this problem, an operation called seasoning becomes necessary by which proper chemical substances are attached to obtain a state like the mass production state. Seasoning is a method often used for etching a dummy wafer made of bulk silicon or the like and attaching reaction byproducts between the wafer and plasma to the inner wall of a plasma processing chamber. However, it is difficult to determine an end time of seasoning, because the correct process results cannot be obtained if an amount of deposition is too much or too less.

Technique of judging an end time of seasoning is known in JP-A-2004-235312 (corresponding U.S. Ser. No. 10/373,097). This technique proposes a method of estimating whether a product wafer can be processes normally after stopping seasoning, in accordance with a correlation formula between a product wafer and an emission spectrum of plasma monitored during processing a dummy wafer.

### SUMMARY OF THE INVENTION

However, according to the techniques disclosed in JP-A-2002-100611 and the like, for example, even if generation of an abnormal state is predicted which is so severe that the correct process result cannot be obtained only by the process condition adjustment, it is inevitable that a wafer already being processed becomes defective. Therefore, although these techniques are effective for lowering a defect rate, the techniques are not sufficient for predicting generation of a defect and preventing the defect in advance. Particularly in recent years, since the degree of fineness and complicatedness of semiconductor devices and large sizes of wafers is progressing, a defective wafer may cause a large economical loss.

According to JP-A-2004-241500, patterns of variation trends of wafer process results are classified into several patterns, and it is judged whether a current trend is based on which pattern, to thereby predict the process results. However, if a plurality type of product wafers are processed, a trend changes with the type of a product wafer processed immediately before. It is therefore difficult to know the patterns of trends of combinations of product wafers of all types.

JP-A-2004-235312 predicts whether the process result becomes normal, during a dummy wafer is processed. However, used dummy wafers are often used in actual mass production. According to studies made by the present inventors, it has been found that if a used dummy wafer is used, a predicted precision becomes coarse because contamination on the dummy wafer surface operates as external disturbances. Therefore, if a working precision of several nm or smaller is required, it is desired to avoid the influence of contamination of a dummy wafer surface. However, in an actual production line, it is difficult to prepare a dummy wafer whose surface state is already managed.

The present invention has been made in consideration of these problems, and provides plasma processing techniques capable of detecting beforehand generation of a working defect and correctly predicting the process result without using a dummy wafer whose surface state is already managed. In the processing, for example, a process result of a product wafer to be processed after waterless conditioning is predicted at the time of waferless conditioning to judge from the predicted result whether processing is performed or not and prevent beforehand generation of a defect.

According to conventional techniques, the process result of a product wafer cannot be predicted unless in the state of processing a wafer product or in the state similar to the wafer product processing state.

The waterless conditioning conditions differ from the product wafer processing conditions in many points such as a process pressure, a plasma generation power, a bias power and a composition of process gas.. For example, since a product wafer is constituted of a plurality type of thin films, gas used in plasma etching is required to be changed with each thin film. Therefore, etching one product wafer carried out often in several stages to ten and several stages. In contrast, waferless conditioning is executed in about one to three stages at most.

Description will be made of typical plasma processing conditions among respective process stages of product wafer etching and conditioning. Under the product wafer etching conditions, HBr/Cl₂/O₂ gases are mixed at a flow rate of 180/20/2 cc/min with a pressure of 0.4 Pa, a plasma generation power of 500 W and an RF bias of 25 W for attracting ions in plasma. Under the waterless conditioning conditions, SF₆/O₂ gases are mixed at a flow rate of 55/5 cc/min with a pressure of 0.1 Pa, a plasma generation power of 700 W and an RF bias of 0 W for attracting ions in plasma.

A wafer reacts with radicals and ions in plasma on the surface thereof to consume etchant and form reaction byproducts. In the waterless conditioning, reaction byproducts with a wafer will not be formed because the wafer is not placed on an electrode.

As above, the waferless conditioning conditions differ from the product wafer etching conditions in many points. From this reason, there is no consideration at all of predicting a process result of a subsequent wafer, while the wafer conditioning is carried out.

The present inventors have configured the present invention by paying attention to that a wafer process result can be determined from the state of the inside of a plasma processing chamber, i.e., that information on a subsequent wafer process is extracted from the state of the plasma processing chamber during waferless conditioning and a subsequent product wafer process result can be predicted from this information.

The present invention adopts the following measures to solve the above-described problems.

A plasma processing apparatus comprises: a processing chamber for executing a plasma process by generating plasma in a specimen placed state and in a specimen non-placed state, the processing chamber including process gas supply means and plasma generator means; state detector means for detecting a state of plasma in the processing chamber; input means for inputting process result data of a specimen processed in the plasma processing chamber; and a controller including prediction equation forming means for forming a prediction equation of a process result in accordance with plasma state data detected with the state detector means for the plasma process simulating a specimen existing state in the processing chamber in the specimen non-placed state and process result data of the specimen input with the input means and processed by the plasma process in the specimen placed state, and storing the prediction equation, wherein the controller predicts the process result of a succeeding plasma process in accordance with plasma state data newly acquired via the state detector means in the specimen non-placed state and the stored prediction equation.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram illustrating a process sequence according to a first embodiment of the present invention.

FIG. 2 is a diagram illustrating conventional techniques.

FIGS. 3A to 3C are diagrams illustrating examples of waferless conditioning 101.

FIGS. 4A and 4B are diagrams showing the experiment results obtained through prediction at a seasoning step 202 in the sequence of FIG. 3B.

FIGS. 5A and 5B are diagrams showing other experiment results.

FIG. 6 is a diagram showing a plasma processing apparatus according to the embodiment.

FIG. 7 is a diagram showing the details of an apparatus controller 265 shown in FIG. 6.

FIG. 8 is a diagram illustrating an operation method for the plasma processing apparatus of the embodiment.

FIG. 9 is a diagram showing a second embodiment of the present invention.

FIGS. 10A and 10B are diagrams illustrating a method of detecting an end point of waferless conditioning 101 by using a prediction value, in accordance with the operation sequence shown in FIG. 9.

FIG. 11 is a diagram showing a method of calculating prediction values at the same time even if two or more types of product wafers 257 exist.

FIGS. 12A and 12B are diagrams illustrating the calculation result of a prediction value.

FIG. 13 is a diagram illustrating a third embodiment of the present invention.

FIGS. 14A and 14B are diagrams showing prediction values and their normal ranges.

FIG. 15 is a diagram illustrating a fourth embodiment of the present invention.

FIG. 16 is a diagram illustrating another example of a method illustrated in FIG. 15.

FIGS. 17A and 17B are diagrams illustrating a fifth embodiment of the present invention.

FIG. 18 is a diagram illustrating a sixth embodiment of the present invention.

### DETAILED DESCRIPTION OF THE EMBODIMENTS

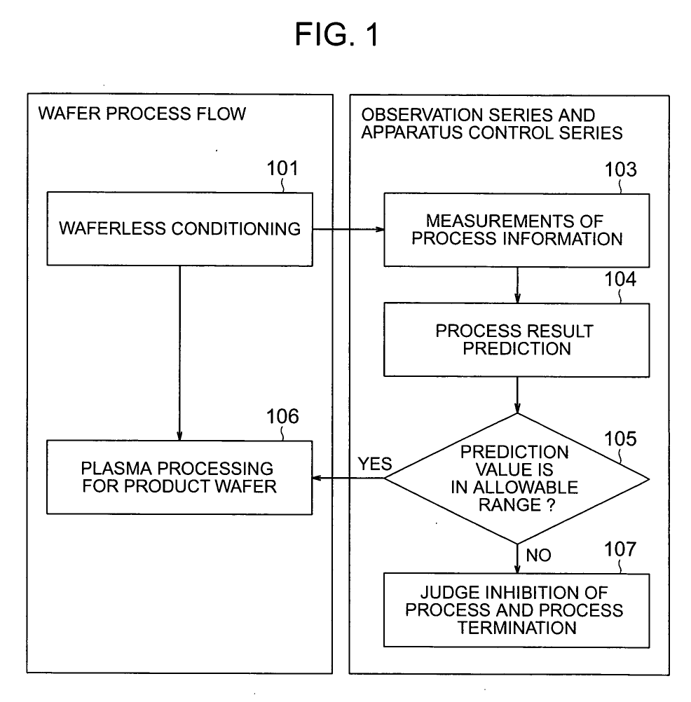

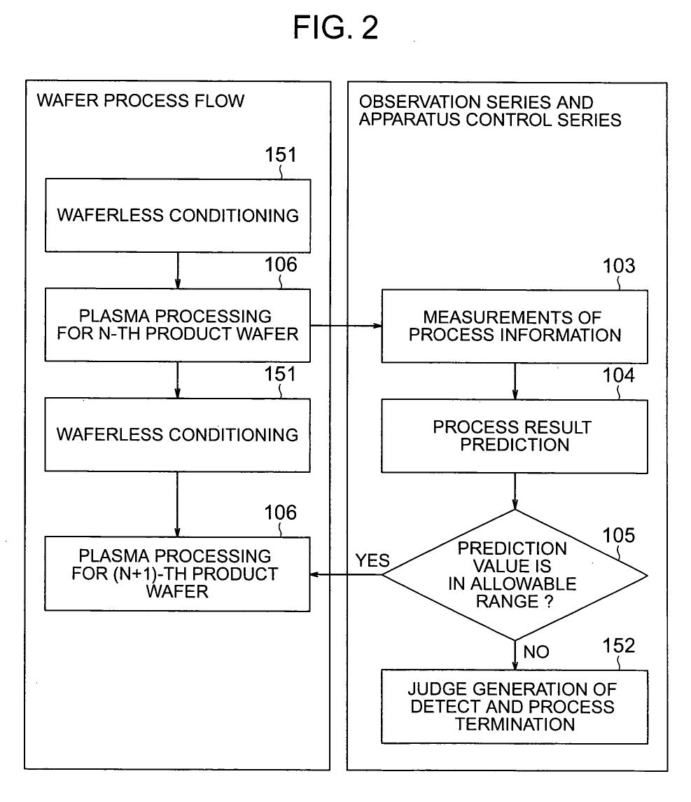

Embodiments will be described with reference to the accompanying drawings. FIG. 1 is a diagram illustrating a process sequence according to the first embodiment of the present invention, and this process sequence will be described by comparing it with the process sequence of conventional techniques shown in FIG. 2.

According to the conventional techniques shown in FIG. 2, an N-th wafer is subjected to a plasma process 106, and measurements 103 are performed to acquire process information such as an emission spectrum of plasma, temperatures in a plasma processing chamber and/or the like. A prediction 104 is performed to predict a process result of the N-th wafer from the results of the measurements 103. A judgement 105 is performed on the basis of a prediction value, and if the prediction value of the process result of the N-th product wafer is in an allowable range, a process 106 starts for an (N+1)-th wafer.

Prior to the process 106, waterless conditioning 151 is performed to remove chemical substances attached during the process 106 and attach proper chemical substances to thereby suppress a variation in process results.

As above, in the plasma processing apparatus, waferless conditioning is performed before each product wafer is processed, and this process is repeated. However, if the judgement 105 indicates that the prediction value of the process result of the N-th product wafer is outside the allowable range, the flow advances to an apparatus control 152 to terminate the process for the (N+1)-th product wafer and prevent defect generation of wafers after (N+1)-th. However, the N-th product wafer is defective.

As different from the conventional techniques, in the process sequence shown in FIG. 1, a process result can be predicted at the time of waferless conditioning 101 before a process 106 for a product wafer. If generation of a defect is predicted at the time of a judgement 105, the flow advances to an apparatus control 107 to terminate the process for a product wafer, perform again the waterless conditioning 101, and the like. Generation of a defect can therefore be suppressed.

As above, according to the invention, generation of a defect can be predicted in advance and avoided.

Next, description will be made on the details of the waferless conditioning 101.

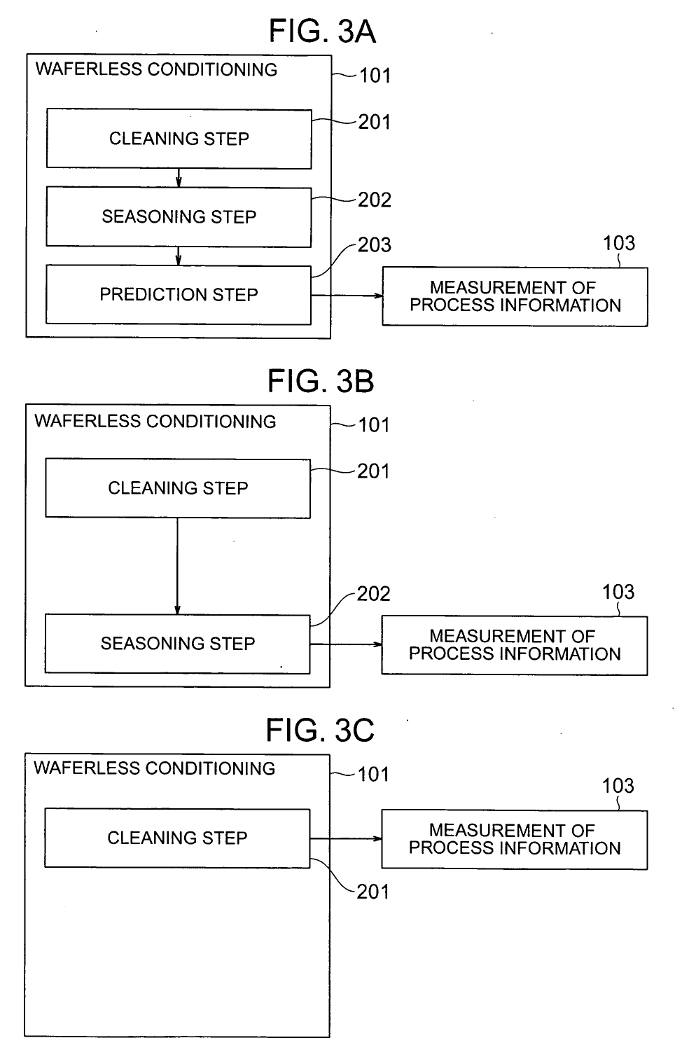

FIGS. 3A to 3B are diagrams illustrating examples of the waterless conditioning 101. In the example of FIG. 3A, the waferless conditioning 101 is divided into a cleaning step 201, a seasoning step 202 and a prediction step 203, measurements 103 are preformed at the time of the prediction step 203, and prediction of a process result shown in FIG. 1 is performed in accordance with the measurement results.

In the example shown in FIG. 3B, the prediction step 203 is not provided and the measurements 103 are performed at the time of the seasoning step 202. In the more simplified example of FIG. 3C, measurements 103 are performed at the time of the cleaning step 201.

In the following, description will be made on an example of etching a semiconductor wafer made of polysilicon by using plasma of SF₆/CHF₃ mixture gas and HBr/Cl₂/O₂ mixture gas. Etching advances by reacting silicon in the wafer with halogen such as F, Cl and Br in plasma and forming SiF₄, SiCl₄, SiBr₄ and the like which are likely to become volatile. If these substances are attached to the inner wall of the plasma processing chamber and oxidized by O, then silicon oxides become resident. Fluorocarbon radicals generated through dissociation of SF₆/CHF₃ by plasma are deposited and become resident on the inner wall of the plasma processing chamber. In order to remove these silicon oxide and fluorocarbon and the like from the inner wall of the plasma processing chamber, plasma of SF₆/O₂ mixture gas is used at the cleaning step 201. F radicals generated in this mixture gas remove silicon oxide in the form likely to become volatile such as SiF₄, whereas O radicals remove fluorocarbon in the form of CO or the like.

The inner wall of the plasma processing chamber immediately after the deposits are removed in this manner has a very high chemical reaction performance. Therefore, the seasoning step 202 changes the state of the inner wall to a chemically stable state by using plasma, or attaches some chemical substances until a chemical equilibrium state is obtained. For example, if a product wafer to be processed after the waferless conditioning 101 is processed by HBr/Cl₂/O₂, then the seasoning step 202 attaches chemical substances by generating also plasma of HBr/Cl₂O₂ mixture gas so that an equilibrium state relative to these gasses can be obtained when a product wafer is processed.

As described above, although the conventional techniques execute the cleaning step 201 and seasoning step 202, the example shown in FIG. 3A additionally uses the prediction step 203.

At the prediction step 203, the state while a product wafer is processed is simulated as much as possible in order to predict a process result of the product wafer to be processed after the waterless conditioning 101. For example, if a product wafer is to be processed by plasma of HBr/Cl₂/O₂ mixture gas after the waferless conditioning 101, the gas to be used at the prediction step 203 is the HBr/Cl₂/O₂ mixture gas added to SiCl₄ and SiBr₄ gasses which are used for simulating reaction byproducts between the silicon wafer and plasma. Alternatively, if a product wafer is to be processed by plasma of SF₆/CHF₃ mixture gas, the gas to be used at the prediction step 203 is the SF₆/CHF₃ mixture gas added to SiF₄ which is used for simulating reaction byproducts between the silicon wafer and plasma.

The gas to be used is determined from the gas to be used for a product wafer to be processed after the waterless conditioning. By adding gas for simulating reaction byproducts, the state at the prediction step 203 is made as near the state while the product is processed as possible. In this state, the measurement 103 is performed for the prediction step 203 to improve a prediction precision of the process result. The process conditions at the predication step 203 have been described above illustratively. In an actual mass production line of product wafer processing, a plurality of stages are executed in almost all cases. For example, a wafer is first processed by plasma of SF₆/CHF₃ mixture gas and then it is processed by plasma of HBr/Cl₂/O₂ mixture gas. In such a case, the prediction step 203 uses the gas which influences the final process result to the largest extent, and the gas for simulating reaction byproducts. It is desired that the gas is selectively used in accordance with the type of a product wafer.

In the above description, the prediction precision is improved by adding the gas for simulating reaction byproducts. However, the process result may be predicted by using the gas which is likely to reflect the state of a plasma processing chamber, without adding the gas for simulating the process while a product wafer is processed. For example, the gas used by the present inventors at the seasoning step 202 is HBr/Cl₂/O₂ mixture gas, HBr and Cl₂ gasses which are likely to reflect the state of a plasma processing chamber. In this case, the prediction 104 is possible by the measurement 103 at the time of the seasoning step 202, without providing the prediction step 203. This embodiment is shown in FIG. 3B. In FIG. 3B, the measurement 103 is performed at the seasoning step 202, and in accordance with the measured value, the process result of a product wafer after the waferless conditioning 101 is predicted.

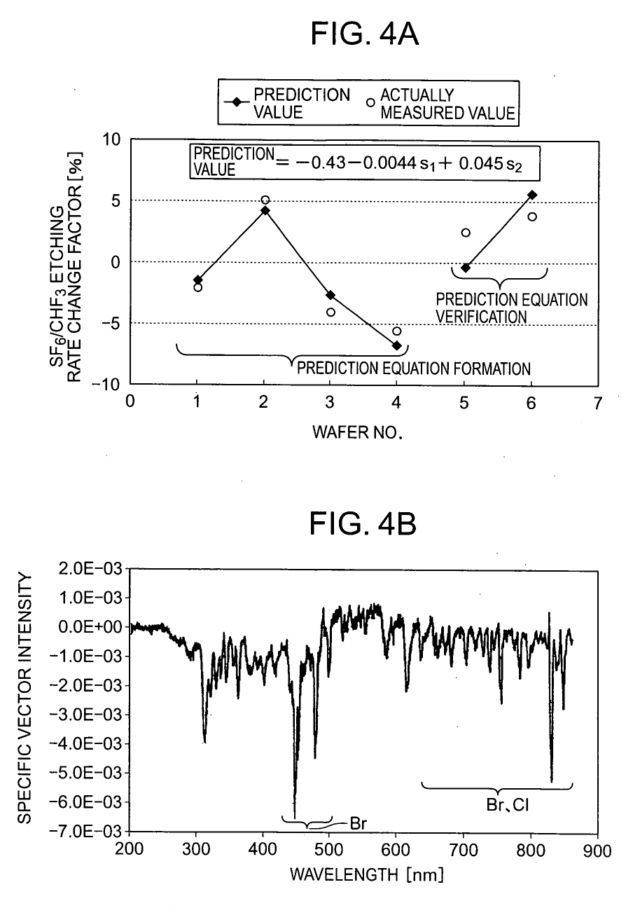

FIGS. 4A and 4B diagrammatically show the experiment results of prediction at the seasoning step 202 in the sequence shown in FIG. 3B. FIG. 4A shows the comparison result between measured values and predicted values calculated from a prediction equation for predicting a change factor in an etching rate of a polysilicon wafer etched with plasma of SF₆/CHF₃ mixture gas. A first principal component score s1 and second principal component score s2 obtained through principal component analysis of an emission spectrum of plasma used at the seasoning step 202 are used as descriptive variables of the prediction equation. The prediction equation is formed by using data of first to fourth wafers, and measured values of fifth and sixth wafers are used for verifying the prediction equation. In this experiment, the change factor of the etching rate was able to be predicted at 3% or smaller than the measured value.

FIG. 4B shows radicals having correlation with etching rates and derived from the emission spectrum of plasma through principal component analysis. Emission peaks of Br and Cl radicals appear in a negative direction. This means that as the etching rate increases, the emission intensities of Br and Cl radicals attenuate, whereas as the etching rate decreases, the emission intensities of Br and Cl radicals increase. Research papers have reported that if chemical substances attached to the inner wall of a plasma etching chamber are organic substances, the emission intensities of Br and Cl radicals attenuate, whereas if attached chemical substances are silicon oxide, the emission intensity increases. It can be presumed that the reason why the etching rate changes in the experiment may be ascribed to these deposits. This experiment indicates that the process result of a product wafer immediately after the waterless conditioning 101 can be predicted by adding Cl₂ and HBr gases which are likely to reflect the state of the inner wall of a plasma processing chamber.

It can be understood from the above-described experiments that the etching rate can be predicted at the time of the seasoning step 202 having the conditions greatly different from the wafer etching conditions. In the experiments shown in FIG. 4, although HBr/Cl₂/O₂ mixture gas is used, other mixture gases may also be used at the seasoning step 202, such as CHF₃, CH₃F, SiCl₄, SiCl₄/O₂, SiF₄/O₂ and CF₄/HBr, and these gases mixed with Ar or He. The present invention may be used by using these gases at the seasoning step.

According to another experiment, a process result was able to be predicted in accordance with the measurement 103 made at the time of only the cleaning step 201 in the sequence shown in FIG. 3C. In this case, the cleaning step 201 was executed by using plasma of SF₆/O₂ mixture gas, after the waferless conditioning, the product wafer was etched by plasma of HBr/Cl₂/O₂ mixture gas to form gates of a CMOS device, and the gate widths were evaluated.

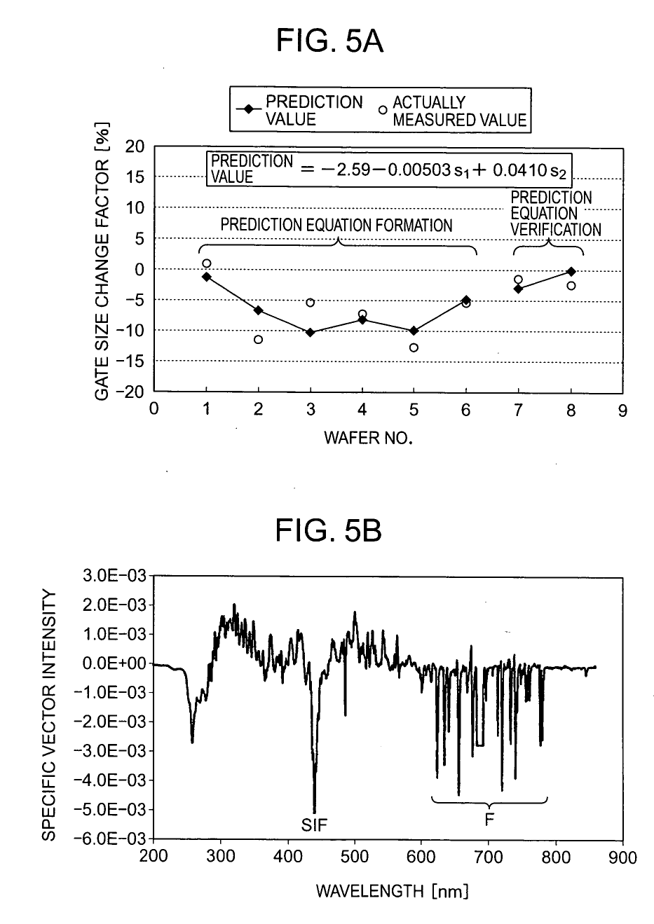

FIGS. 5A and 5B show the results of this experiment. FIG. 5A shows the comparison results between a prediction equation and measured values. First to sixth wafers were used for forming the prediction equation, and seventh and eighth wafers were used for verifying the prediction equation. A difference between predicted values by the prediction equation and measured values was 5% or smaller.

FIG. 5B shows specific vector intensities obtained by deriving radicals having a correlation with gate sizes from the emission spectrum of plasma through principal component analysis. Peaks of fluorine and SiF appear in the negative direction. This means that as the gate size becomes small, the emission intensities of fluorine and SiF radicals increase. A rectangular negative peak appearing near a wavelength of 690 nm is formed because the emission peak at this wavelength exceeds the sensitivity scale of a spectrometer, and is a peak of fluorine. It can be considered from the specific vector intensities shown in FIG. 5B that fluorine and fluorine-containing silicon compound resident even after the waterless conditioning enhance etching of a subsequent product wafer so that the gate size becomes small (narrow). These experiments indicate that the state of the inner wall of a plasma processing chamber can be known even at the cleaning step 201 for removing chemical substances attached to the inner wall, and that the process result of a product wafer immediately after the waferless conditioning 101 can be predicted. In the experiments shown in FIGS. SA and 5B, although SF₆O₂ mixture gas is used, other mixture gases may also be used at the cleaning step 201, such as CHF₄O₂, CHF₃/O₂, C₂F₆/O₂ and F₂O₂, and these gases mixed with Ar or He. If the process result of a product wafer can be predicted at the cleaning step 201 by using these gases, the present invention may be reduced in practice without providing the prediction step 203.

Although SF₆/CHF₃ and HBr/Cl₂O₂ are described as the examples of mixture gases for processing a wafer, mixture gases such as HBr/CH₄/O₂/Ar and CHF₃/O₂/Ar may be used to predict the process result of etching an organic antireflection film on the wafer. In the antireflection film etching process, an etching mask width may be intentionally changed through etching, deposition film attachment or the like. The apparatus and method of the present invention may be used to predict a mask width after change. The present invention is applicable not only to etching Si portion of a wafer, but also applicable widely to semiconductor wafer processing such as organic film etching and deposition film attachment.

As described above, it became apparent also from the experiments that the process result of a product wafer to be subjected to a plasma process after the waterless conditioning could be predicted from the emission spectrum of plasma during the waferless conditioning. The predicted value is compared with a normal range of the process result of a product wafer, and if the predicted value is in the normal range, the product wafer is subjected to a plasma process after the waterless conditioning 101, whereas if the predicted value is out of the normal range, the process is inhibited to avoid a defect in advance.

The invention is not limited to the examples of the waferless conditioning 101 shown in FIGS. 3A to 3C. The waterless conditioning 101 may have only the seasoning step 202 to perform the measurement 103 at the same time as that of the seasoning step. If the process result can be predicted by a step of simply raising a temperature of a plasma processing chamber, this temperature raising step may be provided to perform the measurement 103 at the same time. The waterless conditioning 101 may be designed freely because the feature of the present invention resides in that the process result is predicted through the measurement 103 during the waterless conditioning 101.

As described above, in order to predict the process result of a subsequent product wafer during the waterless conditioning 101, the state while the product wafer is processed is simulated as much as possible or the gas likely to reflect the state of the plasma processing chamber is used for generating plasma. However, some of chemical substances attached to the inner wall of a plasma processing chamber are hard to be desorbed or absorbed. In such a case, the state that deposits are likely to be evaporated is formed by heating the inner wall of a processing chamber, or the state that chemical substances are likely to be absorbed is formed by cooling the inner wall, to thereby form the state that plasma is likely to reflect the state of the inner wall. If chemical substances on the inner wall of a processing chamber contains substances hard to be desorbed such as platinum, for example, an electric field for attracting ions in plasma is applied to the inner wall of a plasma processing chamber. In this case, a prediction precision can be improved by extracting information on chemical substances pulled out by ion sputtering from the emission spectrum of plasma.

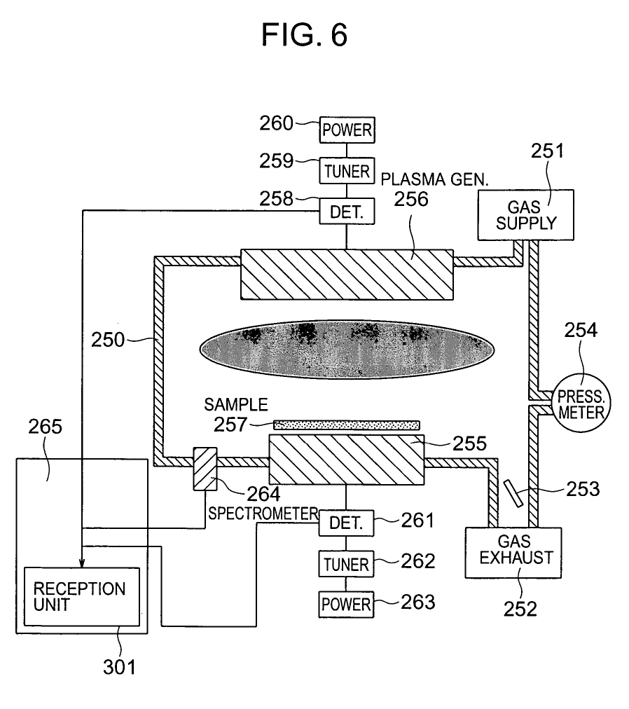

FIG. 6 is a diagram showing a plasma processing apparatus according to the embodiment. A plasma processing chamber 250 for subjecting a wafer to a plasma process has therein a gas supply unit 251 for supplying a process gas, a valve 253 for controlling a pressure in the plasma processing chamber 250 by exhausting the process gas, a gas exhaust unit 252 and a pressure meter 254. The plasma processing chamber 250 has therein also a plasma generator 256 for generating plasma. The plasma generator 256 is equipped with a power source 260 for supplying a power to the plasma generator and a tuner 259 for adjusting an impedance.

The plasma processing chamber 250 has therein a stage 255 for supporting a wafer 257 to be processed. The stage 255 is equipped with a power source 263 for supplying a power to the stage and a tuner 262 for adjusting an impedance.

For the experiments shown in FIGS. 4A and 4B and FIGS. 5A and 5B, an apparatus controller 265 was installed on the plasma processing apparatus, the controller having a spectrometer 264 as a condition detector and a reception unit 301 for receiving a signal output from the spectrometer 264. The spectrometer 264 is SD2000 made of Ocean Optics, Inc. which separates a wavelength from about 200 nm to 900 nm into 2048 channels and outputs a signal of each channel. The reception unit 301 of the controller 265 receives an output signal from the spectrometer 264, and in accordance with the output signals, a process result is predicted and the plasma processing apparatus is controlled.

Instead of the spectrometer 264, state detector units 258 and 261 may be used. The state detector units 258 and 261 are a current detector or voltage detector installed on a path for supplying a power to the plasma generator 256 and stage 255. In addition to the spectrometer, the state detector unit may be one of a current/voltage phase difference detector, a power travelling wave detector, a reflected wave detector and an impedance monitor. If an a.c. power is to be supplied, the state detector units 258 and 261 are preferably provided with a mechanism of separating a detected current and voltage into frequencies through Fourier transform and outputting several to ten and several signals. The invention can be embodied by using one of the state detector units 258, 261 and 264 and transmitting an output signal to the reception unit 301. In the following description, the spectrometer 264 is used as the state detector unit.

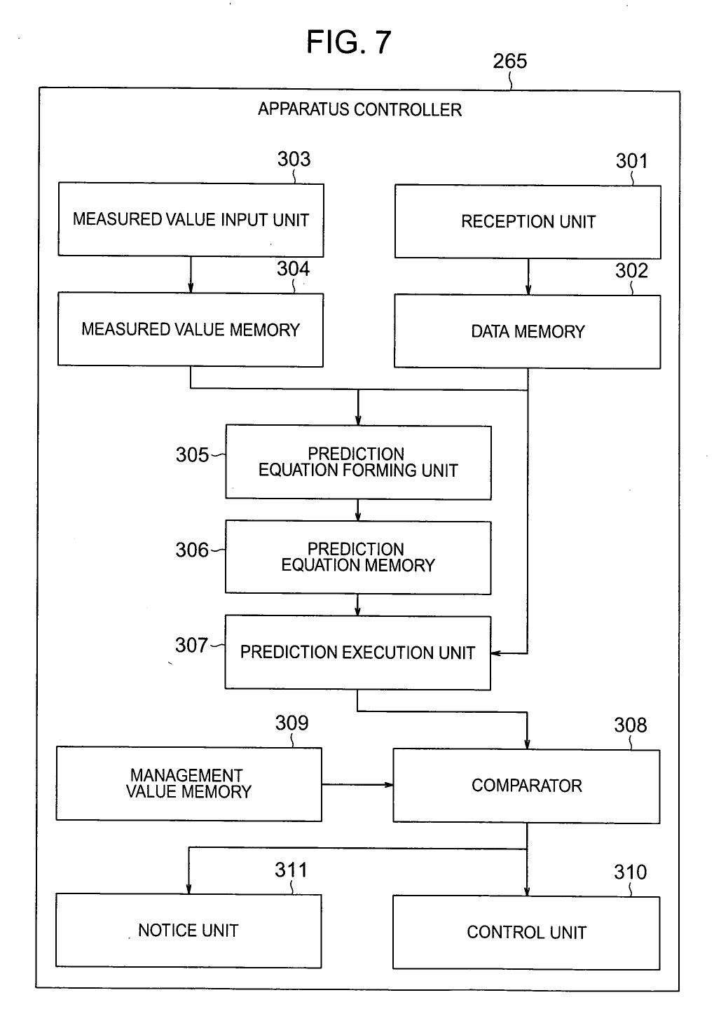

FIG. 7 is a diagram showing the details of the controller 265 shown in FIG. 6. The controller 265 has been described as a single computer, for example, for the experiments shown in FIGS. 4A and 4B and FIGS. 5A and 5B. In this embodiment, the controller 265 may be a plurality of computers interconnected by a network, or a portion of the plasma processing apparatus.

The reception unit 301 of the controller 265 receives an output signal from the spectrometer 264 or the like and stores it in a data memory 302. If data compression is required, necessary calculations such as principal component analysis are executed at the stage of storing the output signal. The controller 265 executes a plasma process for the wafer 257, and receives a process result measured with a measuring apparatus such as an electron microscope and a film thickness interferometer, or the like, via a network interface connected to the measuring apparatus or via a measured value input unit 303 such as a keyboard and a touch panel from which a manager inputs a measured value directly. An input to the measured value input unit 303 is stored in a measured value memory 304.

Next, if necessary, data is read from the data memory 302 and the corresponding measured value is read from the measured value memory 304, and the data and measured value are input to a prediction equation forming unit 305. In accordance with the data input from the data memory 302, the prediction equation forming unit 305 forms a prediction equation capable of predicting a measured value, and stores it in a prediction equation memory 306. In forming the prediction equation, although it is preferable to use principal component analysis similar to the experiments shown in FIGS. 4A and 4B and FIGS. 5A and 5B, multivariate analysis may be used, or calculation results obtained from a difference or ratio of signals such as target radical emission intensities may be used as descriptive variables.

When prediction of a process result becomes necessary, a prediction execution unit 307 reads necessary data from the data memory 302, executes necessary calculations such as principal component analysis, and inputs the calculated data to the prediction equation read from the prediction equation memory 306 to obtain a prediction value of the process result of the wafer 257. A comparator 308 compares the prediction value output from the prediction execution unit 307 with a normal range stored in a management value memory 309. The normal range stored in the management value memory 309 is defined by upper and lower limits of the process result of the wafer 257 and can be set by the apparatus manager.

If the comparator 308 judges that the prediction value is in the normal range, this effect is output to a control unit 310 which in turn controls the plasma processing apparatus to continue the operation. If the comparator 308 judges that the prediction value is out of the normal range, this effect is output to the control unit 310 and a notice unit 311. In reception of this output, the notice unit 311 notifies this effect to the apparatus manager via an unrepresented display, alarm, e-mail or the like. In this case, until an input from the manager is received, the control unit 310 suspends the operation of the plasma processing apparatus. Alternatively, processes necessary for continuation of the operation are executed if possible to resume the operation.

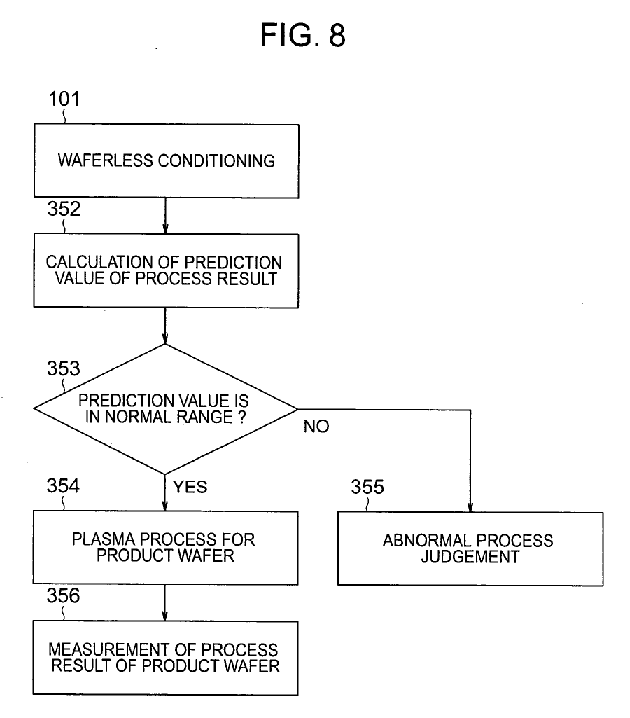

FIG. 8 is a diagram illustrating an operation method for the plasma processing apparatus of the embodiment. First, the waterless conditioning 101 for the plasma processing chamber 250 is performed. As described with reference to FIGS. 3A to 3C, during the waferless conditioning 101, an emission spectrum of plasma is measured with the spectrometer 264, and the measurement result is transmitted to the controller 265. After the waterless conditioning 101 is completed, a calculation 352 for the prediction value is executed.

Next, at a judgement 353 after the calculation 352 for the prediction value, the prediction value is compared with the management value stored in the management value memory 309. If it is judged that the prediction value is in the normal range, the wafer 257 is transported into the plasma processing chamber 250 and a plasma process 354 is executed. If it is judged that the prediction value is out of the normal range, the flow advances to an abnormal process judgement 355. For example, as a process after the abnormal process judgement 355, the waferless conditioning 101 may be executed again or the apparatus may enter a standby state immediately. Alternatively, an upper limit of the number of re-executions of the waferless conditioning 101 may be set beforehand, and if a normal prediction value cannot be obtained after execution of a predetermined number of re-executions, the flow advances to the abnormal process judgement 355.

After the plasma process 354 for the wafer is executed, a process result measurement 356 is performed. After the measurement 356 or plasma process 354 is completed, the waterless conditioning 101 resumes to prepare for the process for the next wafer 257. In a mass production process, if it can be judged that the measured value of the process result and the prediction value are fully in the normal range, it is not necessary to execute the measurement 356 for the process result each time, but the measurement may be executed at a predetermined frequency for confirmation.

After a lapse of a certain time, the state detector units 258, 261 and 264 may have a temporal change. In such a case, prediction may not be performed correctly. For example, if the spectrometer 264 is used as the state detector unit, there occurs a phenomenon that chemical substances are deposited on a observation window unit and a reception light amount reduces. In this case, a received spectrum is deformed even if the emission spectrum of plasma does not change, and it seems that as if the emission spectrum of plasma has changed so that the measurement 103 cannot be made correctly. In order to deal with such a case, the prediction equation is formed again after a lapse of a certain time by using latest data. If the prediction equation is formed by using rather old data, the correct prediction equation may not be formed because of a temporal change in the performance of the spectrometer 264. In this case, the prediction equation may be formed again by excluding old data. Data may be weighted to mitigate the influence of the old data. Conversely, if old data is required to be utilized positively, the prediction equation is formed by positively utilizing the old data.

The first embodiment of the present invention has been described above. According to the first embodiment, by executing the calculation 352 for the prediction value, it becomes possible to judge beforehand whether the process result of the wafer 257 becomes defective or not, so that a defect generation factor can be reduced considerably. Since defect generation is judged by using the prediction value of the process result, the judgement criterion becomes clear.

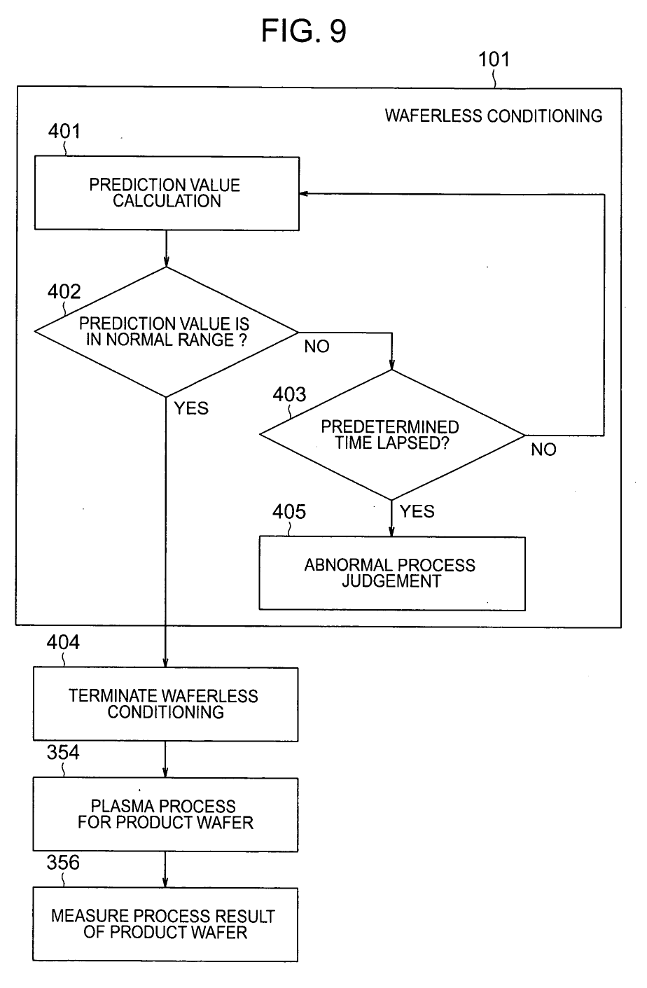

FIG. 9 is a diagram showing the second embodiment of the present invention. In this embodiment, a prediction value is calculated in real time during the waterless conditioning 101 to detect an end point of the waferless conditioning. In this and subsequent embodiments, the structure of the plasma processing apparatus is the same as that of the first embodiment.

As shown in FIG. 9, as the waterless conditioning 101 starts or after a lapse of a predetermined time from the start of the waterless conditioning, a calculation 401 for a prediction value starts using the prediction equation. The calculated prediction value is subjected to a comparison 402 relative to the normal range. If it is judged that the calculated prediction value is in the normal range, the flow advances to a termination operation 404 for the waterless conditioning to thereafter execute a plasma process 354 for the product wafer 257. The plasma process 354 and subsequent processes are similar to those of the first embodiment.

If it is judged at the comparison 402 that the calculated prediction value is out of the normal range, the flow advances to a confirmation 403 for the waterless conditioning time. If it is confirmed that the waferless conditioning time is before a predetermined time, the flow returns to the process 401 to continue the waterless conditioning and prediction value calculation. This cycle is performed in real time. The cycle is preferably once per 1 second or shorter. If it is judged at the confirmation 403 for the waferless conditioning time that the predetermined time has lapsed, the flow advances to an abnormal process judgement 405 to execute necessary processes such as a process termination.

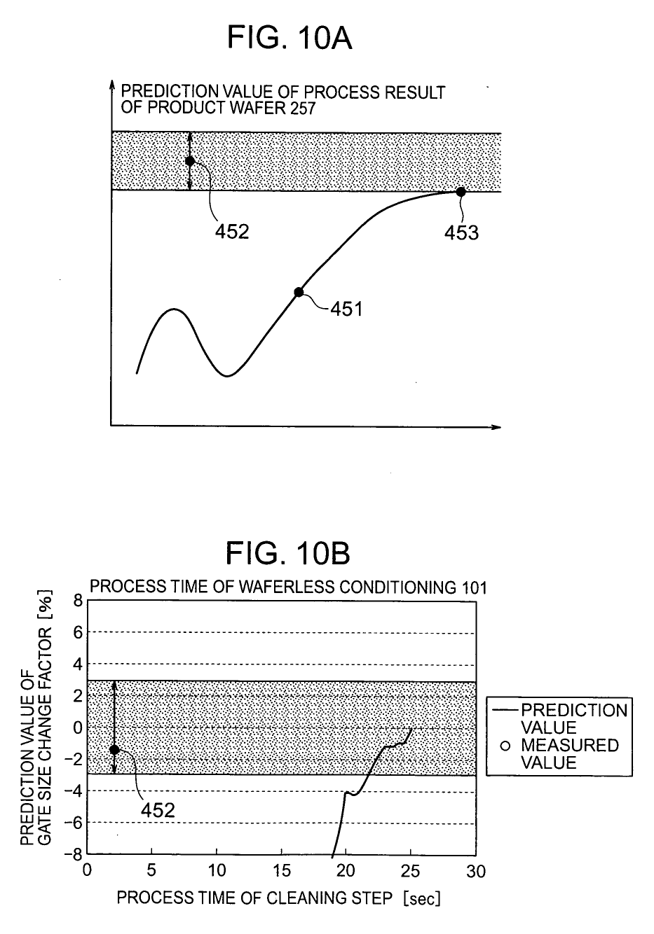

FIGS. 10A and 10B are diagrams illustrating a method of detecting an end point of the waterless conditioning 101 by using the prediction value in accordance with the operation sequence shown in FIG. 9. A curve 451 in FIG. 10A indicates a change in the prediction value of the process result obtained by executing the plasma process 354 for the wafer 257, during the waterless conditioning 101. A range 452 is a range of the normal process result read from the management memory 309.

As shown in FIG. 10A, the prediction value out of a normal range 452 at the initial stage of the waterless conditioning 101 moves near to the normal range 452 as the waterless conditioning 101 progresses, and enters the normal range 452 at the last stage. It is judged that an end point 453 of the waterless conditioning 101 is at the time when the prediction value fully enters the range 452, and the flow advances to the process 354. A screen such as shown in FIG. 10A is displayed on an unrepresented display to make the apparatus manager judge manually the end point, or more preferably the controller 265 judges automatically the end point. The waterless conditioning 101 may be terminated after the waterless conditioning 101 is made to continue for a predetermined time after the end point 453 is detected.

FIG. 10B shows a change in the prediction value obtained by the experiments shown in FIGS. 5A and 5B to verify the embodiment. The prediction value is that of the eighth wafer of the experiments shown in FIGS. 5A and 5B. The abscissa represents a process time of the cleaning step 201 of the waferless conditioning 101. The normal range of a gate size is from −3% to +3%. As the cleaning progressed, the prediction value increased gradually, and the waterless conditioning was terminated at 0%, with a change factor of the prediction value being −2.4%. The end point 453 of the waterless conditioning 101 can be obtained in this manner when the prediction value of the process result enters the range of the normal process result, by calculating the prediction value in real time during the waterless conditioning 101.

As the end point 453 of the waterless conditioning 101 is obtained correctly, the normal process result of the wafer 257 can be obtained more reliably. It is also possible to prevent the normal process from not being executed due to excessive waferless conditioning 101 and to prevent excessive consumption of apparatus components by plasma, otherwise resulting in reduction of the defect factor of wafers 257 and apparatus maintenance cost.

According to the conventional techniques, the end point is detected by monitoring the emission intensity or the like of particular chemical substances. Problems arise therefore, such as a change in the process result to be caused by substances other than the monitored chemical substances and indefinite setting of the normal range 502. In this embodiment, since the end point is managed by using the prediction value, the values of the normal range 452 can be made definite and the end point 453 can be obtained more reliably.

A correct prediction equation is required to be formed in order to obtain a correct end point 453. In forming the prediction equation, the first point to be paid attention is to use only the signal immediately before the waferless conditioning 101 is terminated, among signals from the spectrometer 264. The state nearer to the apparatus state in an actual plasma process for the product wafer 257 can be obtained at the time nearer to the termination of the waferless conditioning 101. Information obtained at the time nearer to the termination is important. However, a large change when plasma is extinguished immediately before the termination is contained in the signal from the spectrometer 264, so that a correct prediction equation cannot be formed.

The second point to be paid attention is to use the state detector units such as the spectrometer 264 having a high sensitivity. The state of the plasma processing chamber 250 during the time zone just while the waferless conditioning 101 is terminated is almost definite. However, this state has a slight temporal change which changes the process result of the product wafer 257. If the spectrometer 264 is to be used, it is therefore necessary to use a spectrometer having a high wavelength resolution and small noises. The spectrometer has preferably the resolution and S/N ratio equivalent to or higher than those of the spectrometer SD2000 made of Ocean Optics Inc. and used by the experiments (which separates a wavelength from about 200 nm to 900 nm into 2048 channels).

In the embodiments described above, one type of product wafers is used. However, in mass production, there is a case that a single plasma processing apparatus processes a plurality of types of product wafers under different process conditions. In such a case, history of which types of product wafers were processed is left as deposits in the plasma processing chamber and may influence the process result of a product wafer. Description will be made on a method capable of calculating prediction values of two or more types of production wafers 257 at the same time in either of the first and second embodiments.

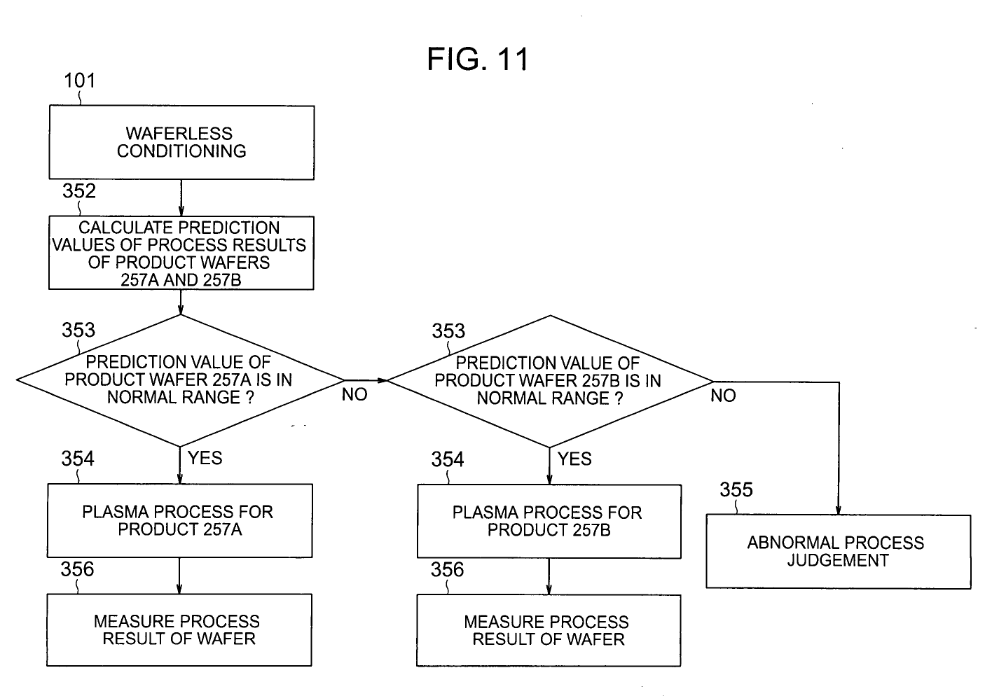

FIG. 11 is a diagram illustrating a method of calculating prediction values at the same time even if there are two or more types of production wafers 257. As shown, it is assumed that two types of product wafers 257A and 257B exist and the process conditions of the process 201 in the waterless conditioning 101 are common to two types of product wafers. It is also assumed that the waterless conditioning 101 is common to both the product wafers.

In this case, the measurement 103 is performed at the cleaning step 201 during the waferless conditioning 101, and the process results of the product wafers 257A and 257B are calculated by using respective prediction equations in accordance with the measured results. If the process result of the product wafer 257A is predicted to be in the normal range, whereas the process result of the product wafer 257B is predicted to be out of the normal range, then the process for the product wafer 257A continues and the process for the product wafer 257B is stopped and the product wafer 257B is processed by another processing apparatus.

Time-consuming maintenance does not start when the process of the product wafer 257B is stopped, but the process for the product wafer 257A continues so that the apparatus operation rate can be improved.

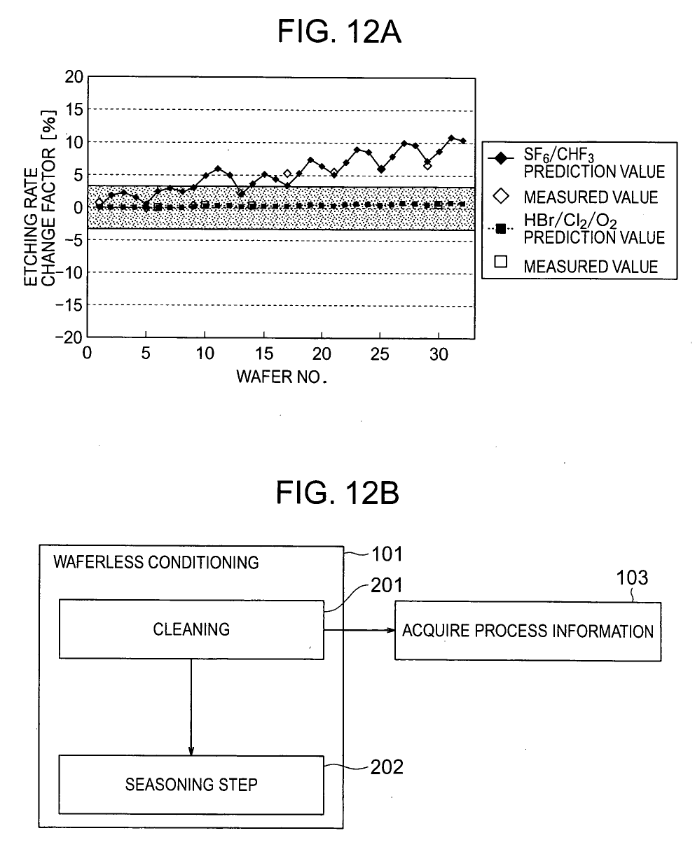

FIGS. 12A and 12B are diagrams illustrating calculation results of prediction values. FIG. 12A shows the calculation results, and FIG. 12B illustrates a calculation sequence. The example shown in FIG. 12A shows predicted etching rates of etching a polysilicon wafer by SF₆/CHF₃ mixture gas and HBr/Cl₂/O₂ mixture gas. Two prediction values are obtained for each wafer because the process results of two types of wafers are calculated at the same time as described above. In the process sequence shown in FIG. 12B, the measurement 103 was performed during the cleaning step 201 using SF₆/O₂ mixture gas and thereafter the seasoning step 202 was executed. The abscissa of FIG. 12A represents a wafer number. The etching rates by SF₆/CHF₃ mixture gas were measured for first, fifth, ninth, thirteenth, seventeenth and twenty first wafers, and it was verified that the etching rates by the same mixture gas can be predicted for twenty fifth and twenty ninth wafers. The etching rates by HBr/Cl₂/O₂ mixture gas were measured for second, sixth, tenth and fourteenth wafers, and it was verified that the etching rate by the same mixture gas can be predicted for a thirtieth wafer. Other wafers are Si dummy wafers etched under the same conditions as those for mass production wafers. Similar to the other experiments, the prediction equations are formed by main composition analysis.

It can be seen from these results that the etching rate by SF₆/CHF₃ mixture gas gradually increases and becomes out of the normal value range indicated by a grey belt for the wafers near the tenth wafer. The experiment value shows the correct result for the thirteenth wafer. However, the tenth wafer has already the abnormal process result as indicated by the behavior of prediction values. In contrast, the etching rate by HBr/Cl₂/O₂ hardly changes starting from the initial stage, the prediction values continue to take the normal values even for the consecutive fifteenth to twenty ninth wafers not etched with HBr/Cl₂/O₂, and the prediction value for the thirtieth wafer still takes the normal value. As apparent from these experiments, the prediction value of the process result of a wafer can be monitored always while another wafer is processed. It is therefore possible to judge whether the wafer not processed during a certain period can be processed normally.

This can be applied to detecting the end point of the second embodiment. For example, if the end point of the product wafer 257B is not still obtained although the prediction value of the product wafer 257A enters the normal range and the end point is obtained, the waferless conditioning 101 continues to provide a high reliability plasma process for both the product wafers. Alternatively, if the product wafer 257A is to be processed, the waterless conditioning 101 is terminated at the end point of only the product wafer 257A, and conversely if the product wafer 257B is to be processed, the waferless conditioning 101 is terminated at the end point of only the product wafer 257B. In this manner the state, i.e., process environment of the inner wall surface of the plasma processing chamber 250, can be used selectively between the product wafers 257A and 257B.

In the above description, although two types of the product wafers 257A and 257B are used, for example, the product wafer 257A may have two or more values to be monitored. In this case, the first value is assigned to a product wafer 257A1, the second value is assigned to a product wafer 257A2, and the method quite the same as that described above can be used.

In addition to the product wafer, the process result may also be predicted for a test wafer having a similar structure to that of the product wafer and a wafer type measurement apparatus. If the wafer type measurement apparatus is a wafer type probe for measuring a current density, the current density is an object to be predicted. Two or more types of test wafers or wafer type measurement apparatus can evaluate more in detail the state of the plasma processing chamber than one type of a test wafer or a wafer type measurement apparatus.

FIG. 13 is a diagram showing the third embodiment of the present invention. The feature of the third embodiment includes the feature of the first embodiment and a recovery step 503 for the apparatus to be executed when the prediction value does not enter the normal range. Similar to that the second and first embodiments may be combined, the second and third embodiments may be combined.

In FIG. 13, the waterless conditioning 101 and processes 352 to 356 are similar to those of the first embodiment and the description thereof is omitted.

If it is judged at the judgement 353 that the prediction value is out of the normal range, the flow advances to a judgement 501. The judgement 501 judges whether a setting 502 for a recovery step condition and a recovery step 503 are repeated a predetermined number of times. If the processes are executed the predetermined number of times or more, the flow advances to the abnormal process judgement 355. If the processes are not executed the predetermined number of times or more, the flow advances to the setting 502 for the recovery step condition. In the setting 502 for the recovery step condition, the condition of the next recovery step 503 is set in accordance with the prediction value calculated by the prediction value calculation 352. If the setting 502 for the recovery step condition is to be executed automatically, the condition may be selected from, for example, an already existing recovery step condition list 504 by using a proper algorithm and in accordance with the prediction value calculated at the prediction value calculation. 352, or an optimum condition may be calculated from the condition in the list 504. Alternatively, an apparatus manager may set the condition manually in accordance with the prediction value calculated by the prediction value calculation 352 or the data obtained by the spectrometer 264.

Although one prediction value may be used, two or more prediction values are used preferably for the condition setting 502.

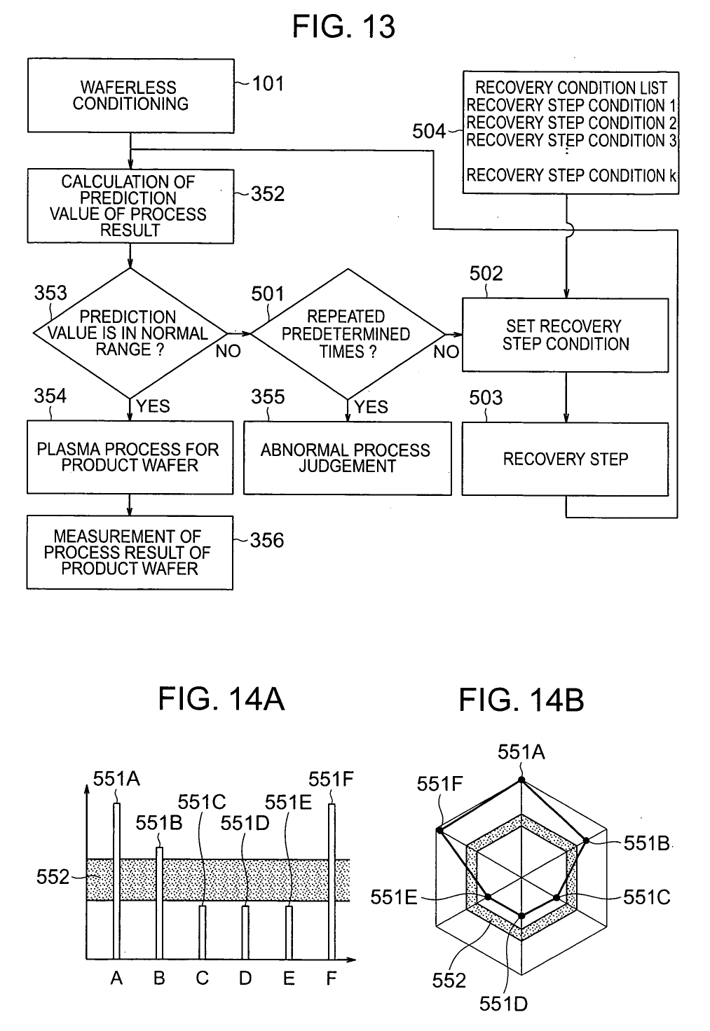

FIGS. 14A and 14B are diagrams showing prediction values and its normal range. Prediction values are calculated, for example, for six wafers 257A, 257B, 257C, 257D, 257E and 257F. The prediction values of a bar graph such as shown in FIG. 14A, a polygonal line graph or a radar chart such as shown in FIG. 14B is displayed on a display (not shown) to make an apparatus manager judge and manually set the recovery step condition, or the apparatus itself may judge and set the recovery step condition from the six wafer prediction values by using a proper algorithm.

In FIGS. 14A and 14B, values 551A, 551B, 551C, 551D, 551E and 551F are the prediction values of the wafers 257A, 257B, 257C, 257D, 257E and 257F, and a range 552 is the normal range of the prediction values. As seen from FIGS. 14A and 14B, the values 551A, 551B and 551F are larger than the normal range 552, whereas the values 551C, 551D and 551E are smaller than the normal range. By using such a chart, the setting 502 for the recovery step condition is performed in such a manner that one or more of the values 551 enter the normal range 552.

After the setting 502 for the recovery step condition, the recovery step 503 is executed. The condition of the recovery step 503 includes at least the same step as the prediction step 203 in the waterless conditioning 101. This prediction step 203 calculates again prediction values to judge whether the recovery step succeeds. If the prediction step 203 is integrated with the cleaning step 201, the cleaning step 201 is executed, whereas if the prediction step is integrated with another step, this other step is executed.

As described above, according to the third embodiment, if the prediction value does not enter the normal range, the necessary condition of the recovery step 503 is set in accordance with the prediction value. By using two or more prediction values, the state of the apparatus can be judged synthetically and a more suitable condition of the recovery step 503 can be set.

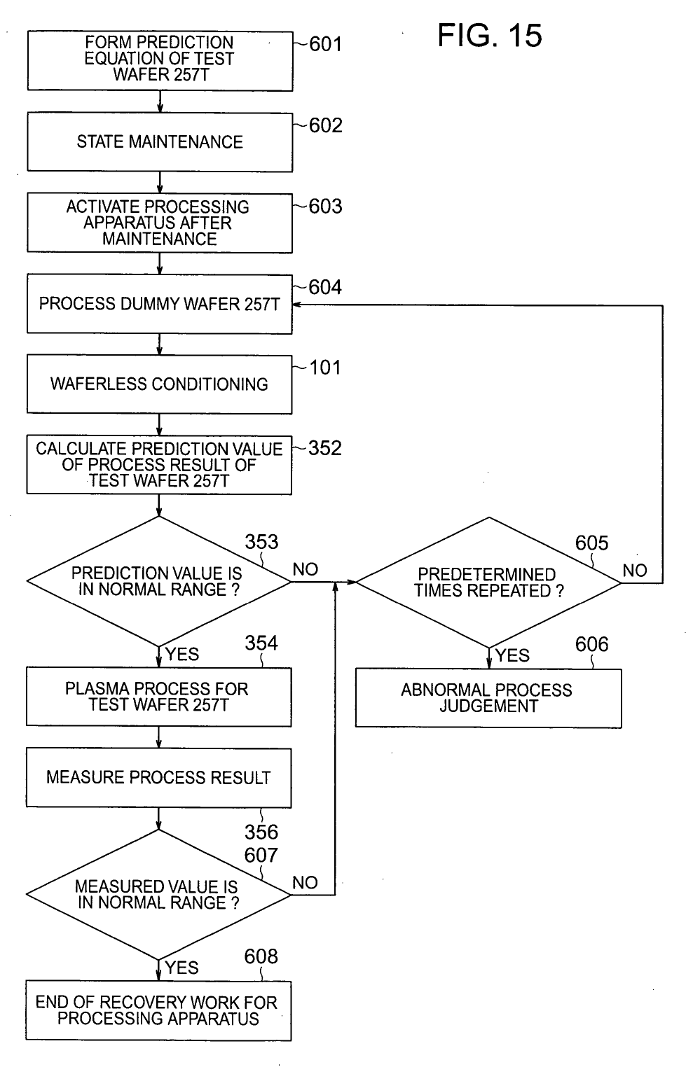

FIG. 15 is a diagram showing the fourth embodiment of the present invention. In this embodiment, description will be made on a recovery method after maintenance of the plasma processing apparatus. The fourth embodiment may be combined with the end point detection method of the second embodiment or the recovery step 503 of the third embodiment.

First, while the processing apparatus operates normally, a step 601 generates beforehand the prediction equation of a test wafer 257T. The particular sequence of this step 601 is similar to the operation sequence of the first embodiment shown in FIG. 8.

Next, when the apparatus is stopped because of the abnormal process judgement 355 or the like, a maintenance 602 starts. After the maintenance 602, the flow advances to an activation 603 of the processing apparatus. After the activation 603, the flow advances to a process 604 for a dummy wafer 257S. An object of this process 604 is to perform the seasoning by which the normal state having some chemical substances is obtained for the inner wall of the plasma processing chamber 250 which has almost no chemical substance attached thereto immediately after the maintenance. After the process 604, the waterless conditioning 101 starts to perform a calculation 352 of the prediction value of the wafer 257T. Next, if a judgement 353 indicates that the prediction value is in the normal range, a process 354 for the wafer 257T starts. If the prediction value is not in the normal range and a judgment 605 indicates smaller than a predetermined number, the flow returns again to the process 604 for the dummy wafer 257S. If the judgement indicates the times equal to or more than the predetermined number, an abnormal process judgement 606 is made. As operations after the judgement 606, for example, the maintenance 602 may be performed again or similar to the third embodiment, the recovery step setting 502 and recovery step 503 may be executed.

If the flow can advance to the process 354 and the plasma process 354 for the test wafer 257T is completed, the flow advances to a measurement 356 for the process result of the wafer 257T. Next, at a judgement the controller 265 reads the normal values of the wafer 257T from the management memory 309, and if the measured value is in the normal range, the flow advances to a process 608 whereat it is possible to judge that the recovery work of the processing apparatus is completed. Thereafter, in accordance with, for example, the first embodiment, the processing apparatus starts operating. If the judgement 607 indicates that the measured value is out of the normal range, the flow advances to a judgement 605.

In the fourth embodiment, if it takes a time to perform the measurement 356 for the process result of the wafer 257T, the processes starting from the process 604 for the dummy wafer 257S may be repeated until the judgement 607 is completed after the measurement 356. Instead of the test wafer 257T, a product wafer 257 may be used. In this case, since the prediction equation is already formed in the ordinary operation, i.e., as in the case of the first embodiment, the process 601 of forming the prediction equation is not necessary.

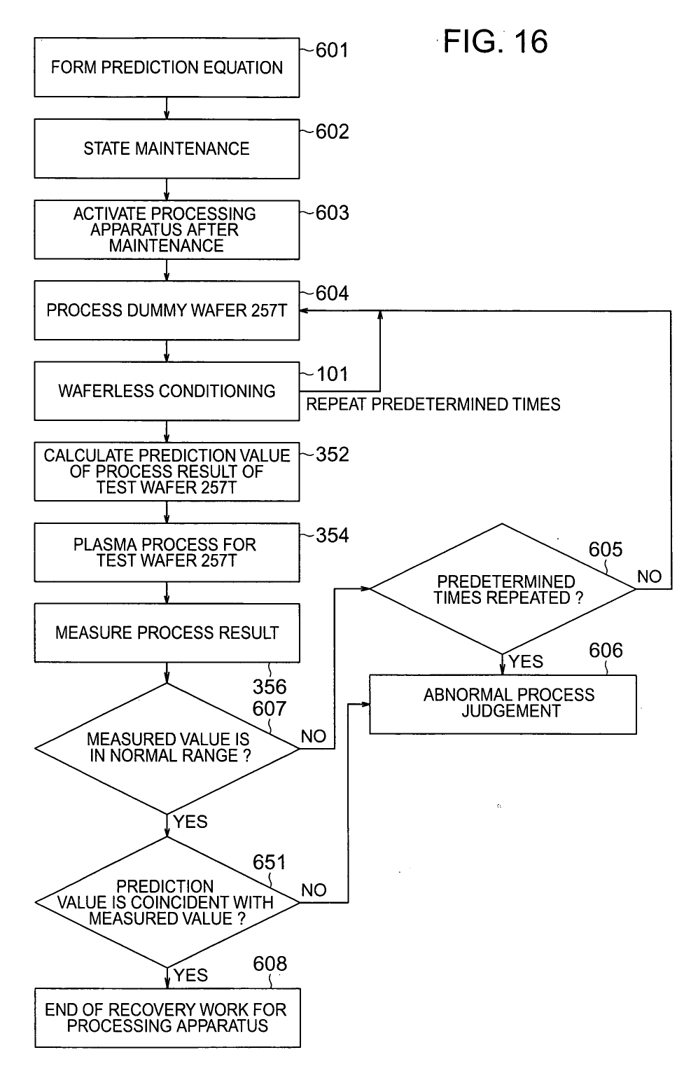

After the maintenance 602, the process result may not be predicted correctly by the prediction equation formed before the maintenance 602, i.e., in the process 601. This is because the observation series of the state detector units 258, 261 and 264 are influenced by the maintenance 602 more or less. For example, if the spectrometer 264 is used as the state detector unit, the influence may be ascribed to that the quantity and quality of chemical substances attached to an observation window are changed by the maintenance 602 so that a reception light amount is changed, or to other reasons. In such a case, the calculation 352 for the prediction value and the judgement 353 do not operate correctly. In this case the sequence shown in FIG. 16 is performed.

FIG. 16 is a diagram illustrating another example of the recovery method after maintenance of the plasma processing apparatus. A different point of FIG. 16 from FIG. 15 resides in a judgement 651. After the activation 603, the process 604 for the dummy wafer 257S and the waferless conditioning 101 are repeated predetermined times, and the calculation 352 for the prediction value of the process result of the wafer 257T is performed. Next, the plasma process 354 for the wafer 257T is executed, and the measurement 356 of the process result is made. After the judgement 607 whether the process result is in the normal range, the judgement 651 is made to judge whether the prediction value is coincident with the measured value, i.e., whether a difference between the prediction value and measured value is smaller than a predetermined value. Coincidence means that the apparatus state and measuring apparatus series before the maintenance are recovered. Therefore, the flow advances to the process 608 whereat the recovery work after the maintenance is terminated. If not coincident, the flow advances to the abnormal process judgement 606.

According to the fourth embodiment, the end point of the recovery work after the maintenance can be obtained reliably. In addition, since the process result can be predicted during the waterless conditioning 101 without the dummy wafer 257S, the influence of surface contamination can be eliminated and prediction can be made at high precision. Although the above description is related to a method of judging the recovery work after the maintenance by predicting the process result of the wafer 257T, if a plurality of process results are predicted, the state of the apparatus can be grasped more correctly and the process after the recovery work can be made reliably.

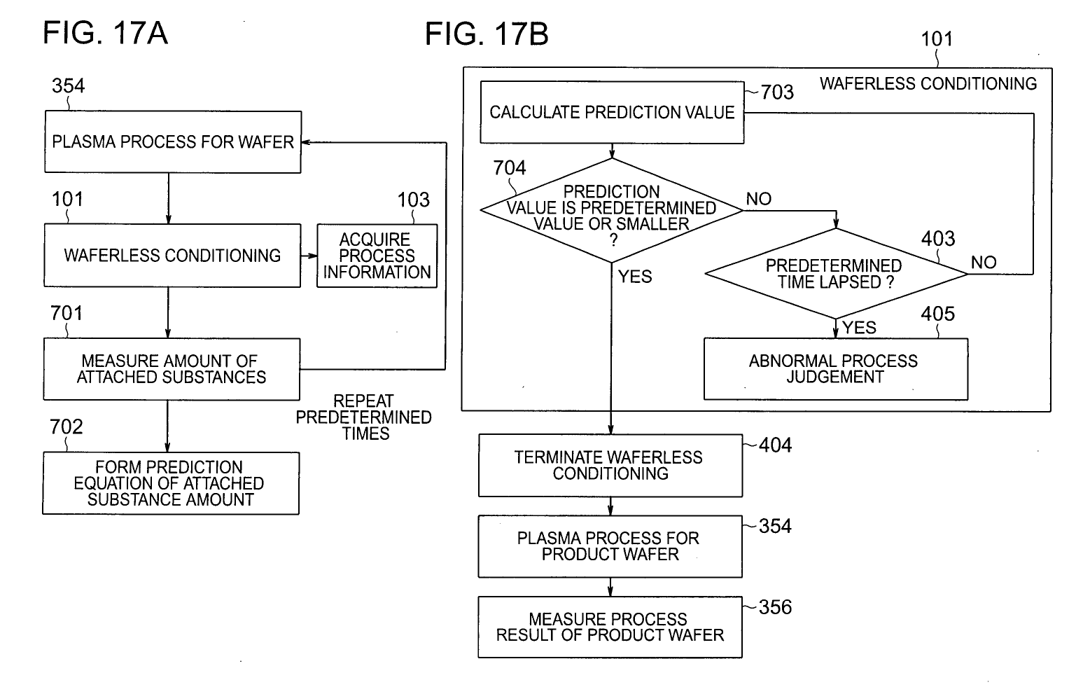

FIGS. 17A and 17B diagrammatically show the fifth embodiment. Description will be made on a method of evaluating the apparatus state by using a virtual measurement apparatus.

Various chemical substances are attached to the inner wall of the plasma processing chamber 250. For example, silicon oxide is one of the attached chemical substances. In order to remove silicon oxide, for example, SF₆ is used as process gas of the waterless conditioning 101 to generate SF₆ plasma and remove silicon oxide in the form of SiFₓ (x=1 to 4). In such a case, although existence of SiF can be observed in the emission spectrum of plasma near at a wavelength of 440 nm, it is difficult to locate silicon oxide itself. Namely, although it is possible to presume a reduced amount of attached silicon oxide on the basis of a sufficient attenuation of the emission intensity of SiF, it is not possible to confirm that silicon oxide is removed completely.

In such a case, a window made of ZnSe is formed on the wall of the plasma processing chamber 250, and it is preferable to use, as the state detector unit 264, so-called Fourier transformation infrared spectroscopy (FT-IR) by which existence of silicon oxide can be detected from the absorption spectrum of infrared rays transmitting through the window. However, since this apparatus is expensive, it is difficult to mount this apparatus on a commercial plasma processing apparatus.

An approach to overcoming this will be described below. As a state detector unit, both a spectrometer 264A and an FT-IR measurement unit 264B are used. The positions of the spectrometer 264A and FT-IR measurement apparatus 264B may be set near to each other. First, as shown in FIG. 17A, prior to shipment of a plasma processing apparatus, a plasma process 354 is executed for a bulk Si dummy wafer to attach deposits to some degree. Next, the waterless conditioning 101 is performed to remove deposits to some degree, and a measurement 103 is made for measuring emission spectrum of plasma with the spectrometer 264A immediately before completion of the waterless conditioning 101, and at the same time a measurement 103 is performed to measure the amount of deposits with the FT-IR measurement apparatus 264A. This work is repeated predetermined times and thereafter a prediction equation is formed for predicting from the emission spectrum the amount of deposits measured with the FT-IR measurement apparatus 264B during the waferless conditioning 101. When the plasma processing apparatus is shipped, the FT-IR measurement apparatus 264B is dismounted and the prediction equation is stored. At the shipped site, a prediction 703 in the sequence shown in FIG. 17B is performed during the waterless conditioning 101 to calculate an amount of deposits in real time. Similar to the end point detection of the second embodiment, the waferless conditioning is performed until the prediction value becomes equal to or smaller than a predetermined value. When the prediction value becomes equal to or smaller than the predetermined value, the waterless conditioning 101 is terminated and a plasma process 354 for a product wafer is executed. In this manner, the amount of deposits can be measured without the FT-IR measurement apparatus 264B, as if the amount of deposits was measured with the FT-IR measurement apparatus 264B. It is therefore possible to detect an end point relative to deposits whose existence is difficult to be judged, for example, from the emission spectrum measured with the spectrometer 264A.

This embodiment is also effective for the detailed evaluation of the state of the plasma processing chamber 250 by using a wafer type current probe or the like. Namely, if a prediction equation is formed for predicting a current value obtained when a wafer type current probe is processed as the wafer 257, it is possible to predict the current value at the next process time during the waferless conditioning 101. The state of the plasma processing chamber 250 can be evaluated more precisely during the waferless conditioning 101, if the types of probes to be used are increased to predict not only current but also electron temperature, electron density, emission intensity distribution and the like and a plurality of prediction values are calculated at the same time as described earlier.

By using such a virtual measurement apparatus, the state of the plasma processing chamber 250 can be known in detail, and the reason of any apparatus abnormality can be found effectively. The plasma processing apparatus can be made more inexpensive than an actual measurement apparatus is mounted.

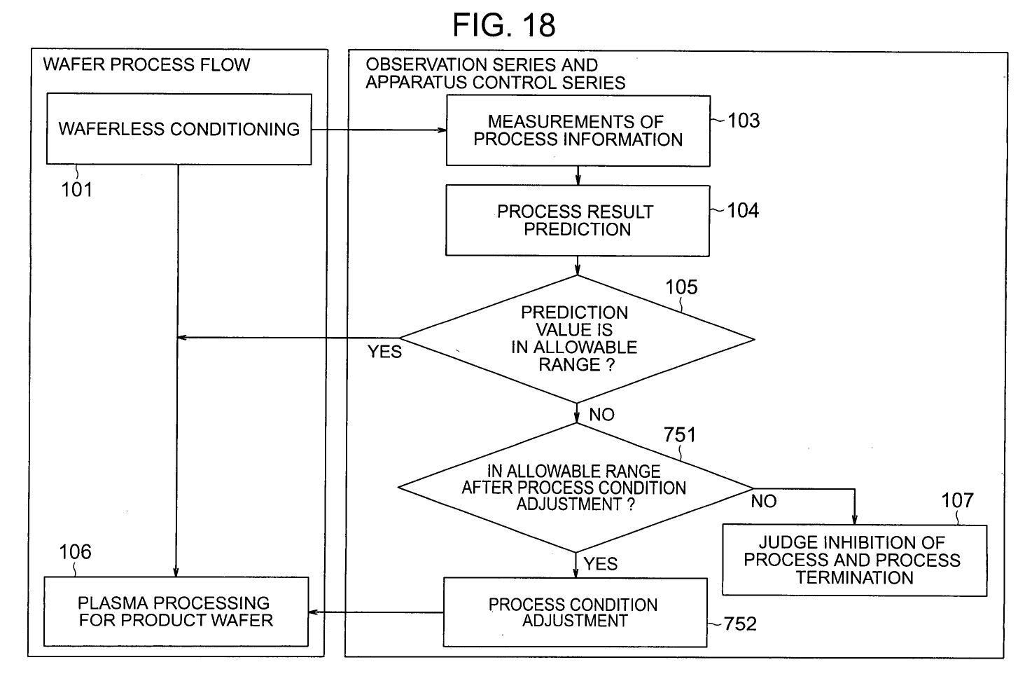

FIG. 18 is a diagram showing the sixth embodiment of the present invention. In this embodiment, a stable process result can be obtained by adjusting the process condition of the plasma process for a wafer 257 in accordance with the prediction value. For example, according to the conventional techniques disclosed in JP-A-2002-100611, the process conditions of an (N+1)-th product wafer 257 is adjusted in accordance with the process result of an N-th product wafer 257 to obtain always a constant process result. However, if the process condition is adjusted, the prediction result at the time of the waterless conditioning 101 of the present invention does not become coincident. If the end point detection of the waterless conditioning 101 and the recovery step of the present invention are executed, these processes become external disturbances to the conventional techniques so that the process condition cannot be adjusted correctly. Namely, the present invention and the conventional techniques cannot be combined simply.

To avoid this, as shown in FIG. 18, the N-th process result is not fed back to the (N+1)-th as in the conventional techniques, and the prediction value during the waferless conditioning 101 is fed back to the product wafer plasma process 106 to adjust the process condition so that the conventional techniques and the present invention can be combined. Each process shown in FIG. 18 is the same as a corresponding one shown in FIG. 1. If the judgement 105 predicts that the process cannot be executed normally, a judgement 751 is made whether the normal result can be obtained by an adjustment 752 of the process condition on the basis of the prediction value. If it is judged that the normal result can be obtained, the adjustment 752 of the process condition is performed so that the process result obtained after the plasma process 106 can be made constant. In this manner, the advantage of the present invention capable of detecting a defect in advance can be incorporated in the conventional techniques.

However, as the process condition adjustment 751 is performed, the prediction of the process result obtained during the waterless conditioning 101 does not coincide with the actual process result. In forming the prediction equation during the waterless conditioning 101, if the process result after the process condition adjustment 751 is used, the process condition adjustment 751 becomes external disturbances so that the prediction equation cannot be formed correctly. In such a case, the adjusted value of the process condition adjustment 751 is added as a correction value to the actual process result, and the prediction equation used by the waterless conditioning 101 is formed by using the correct process result.

The process condition adjustment is not limited to feedback from the waterless conditioning 101 to the product wafer, but it may be fed forward to absorb a variation measured before the plasma process. For example, if a product wafer 257 before the plasma process has a variation in resist patterns, resist patterns are measured before the plasma process. If a resist pattern of the wafer is thicker than an average width, the center value of the normal range 452 is adjusted in amount by a width corresponding to a difference from the average width or the prediction equation is adjusted to reflect the width of the resist pattern and not to reflect the variation in resist patterns on the process result of the plasma process. With such a method, it is possible to correct not only a change in the state of the inner wall of the chamber but also a variation to be caused by a process of forming photoresist or film on a wafer before the plasma process, so that a very high processing precision can be obtained.

The first to sixth embodiments have been described above. The present invention is not limited only to the embodiments and to the above-described hardware structure. For example, although the apparatus processes the wafer 257 in plasma, the wafer 257 is replaced with a glass substrate if the invention is applied to an apparatus for manufacturing liquid crystal displays.

The most characteristic point of the present invention resides in that the process result of a product wafer to be processed after the waferless conditioning is predicted at the time of the waterless conditioning, and the invention is not limited to the above-described hardware structure. For example, the spectrometer 264 may be replaced with a plasma probe inserted into, for example, the plasma processing chamber 250 and being capable of outputting a number of signals like a spectrometer, a gas flow meter installed in the gas supply unit, or a mass analyzer installed at the back stage of the plasma processing chamber 250 or gas exhaust unit 252. A unit utilizing a laser induction fluorescence method, an infrared absorption method or the like may also be used which externally introduces light into the plasma processing chamber 250 and detects an absorption spectrum of light transmitted through or reflected from plasma. Alternatively a unit such as an active probe may be used which externally applies an electric signal and detects its response. These state detector units output a signal representative of the apparatus state at a constant interval or at preset sampling times. Although a detector such as a monochromatic meter for receiving only a single wavelength may also be used, it is preferable to use a detector capable of outputting a number of signals in order to correctly grasp the states of the plasma processing apparatus and plasma. The installation position of the state detector unit 264 is not only the inner wall of the plasma processing apparatus 250 shown in FIG. 6 but also the plasma generator 256 and stage 255.

The present invention can be embodied by using the hardware structure capable of predicting the process result after the waterless conditioning 101, without using plasma during the waferless conditioning 101. Namely, if the waferless conditioning 101 removes chemical substances or attaches proper chemical substances by only flowing high reactive gas in the plasma processing chamber 250, the state detector units 258, 261 and 264 may be a mass analyzer or other units which are independent from electric or optical characteristics of plasma and utilizes a laser induction fluorescence method, an infrared absorption method or the like.

As described above, according to each embodiment of the present invention, it is possible to detect a defect before wafer processing by forming the prediction equation correlating the wafer process result with the state detection data of the plasma processing chamber during the waterless conditioning immediately before the wafer process. Generation of detects can therefore be minimized.

Since the end point of the waferless conditioning can be detected reliably, it is possible to prevent degradation of the apparatus status and consumption of apparatus components to be caused by excessive waterless conditioning. Since the process results of all types of wafers can be predicted during the waterless conditioning, it is possible to predict always whether a defect is formed in all types of wafers. Since the process for a wafer predicted to become a defect can be stopped and the process for a wafer predicted to be processed normally can continue, the operation rate of the plasma processing apparatus can be improved.

It is possible to clearly grasp the apparatus state by a plurality of types of prediction values so that a proper recovery step condition can be set even if an abnormal apparatus state is detected and a recovery step is required. A virtual measurement apparatus can be mounted. It is therefore possible to grasp the apparatus state more in detail and to perform trouble shooting effectively.

The present invention may be combined with the conventional techniques. Since most of the hardware structures are common to those of the conventional techniques, the present invention can be used without considerable alterations or additional installations and can be embodied very easily.

The present invention can provide plasma processing techniques capable of detecting working defects in advance and predicting the process result reliably without using a dummy wafer whose surface state is already managed.

Other aspects of the invention are as follows:

1. A process result prediction method for a plasma processing apparatus including: a processing chamber which performs a plasma process by generating plasma in a specimen placed state and in a specimen non-placed state, said processing chamber including a process gas supplier and a plasma generator; a state detector which detects a state of plasma in said processing chamber; and an input unit which inputs process result data of a specimen processed in said plasma processing chamber, the method comprising steps of:

in performing the plasma process, simulating a specimen existing state in said processing chamber in the specimen non-placed state,

forming a prediction equation of a process result in accordance with plasma state data detected with said state detector and process result data of the specimen input with said input unit and processed by the plasma process in the specimen placed state; and

predicting the process result of a succeeding plasma process in accordance with said formed prediction equation and plasma state data newly acquired via said state detector in the specimen non-placed state.

2. A process result prediction method for a plasma processing apparatus including: a processing chamber for executing a plasma process by generating plasma in a specimen placed state and in a specimen non-placed state, said processing chamber including process gas supply means and plasma generator means; state detector means for detecting a state of plasma in said processing chamber; and input means for inputting process result data of a specimen processed in said plasma processing chamber, the process result prediction method comprising steps of:

forming a prediction equation of a process result in accordance with plasma state data detected with said state detector means for the plasma process in the specimen non-placed state and process result data of the specimen input with said input means and processed by the plasma process in the specimen placed state; and

predicting the process result of a succeeding plasma process in accordance with the formed prediction equation and plasma state data newly acquired via said state detector means in the specimen non-placed state.

3. The process result prediction method for a plasma processing chamber according to aspect 1, wherein said plasma processing chamber is heated or cooled or an ion attracting electric field is generated in said plasma processing chamber, respectively for a process in the specimen non-placed state.

4. The process result prediction method for a plasma processing chamber according to aspect 2, wherein said plasma processing chamber is heated or cooled or an ion attracting electric field is generated in said plasma processing chamber, respectively for a process in the specimen non-placed state.

5. The process result prediction method for a plasma processing apparatus according to aspect 1, wherein the plasma state data to be detected with said state detector for the process in the specimen non-placed state is acquired immediately before completion of the plasma process.

6. The process result prediction method for a plasma processing apparatus according to aspect 2, wherein the plasma state data to be detected with said state detector for the process in the specimen non-placed state is acquired immediately before completion of the plasma process.

7. The process result prediction method for a plasma processing apparatus according to aspect 1, wherein the process result is predicted in real time.

8. The process result prediction method for a plasma processing apparatus according to aspect 2, wherein the process result is predicted in real time.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a processing chamber which performs a plasma process by generating plasma in a specimen placed state and in a specimen non-placed state, said processing chamber including a process gas supplier and a plasma generator;
a state detector which detects a state of plasma in said processing chamber;
an input unit which inputs process result data of a specimen processed in said plasma processing chamber; and
a controller including a prediction equation former which forms a prediction equation of a process result in accordance with plasma state data detected with said state detector for the plasma process simulating a specimen existing state in said processing chamber in the specimen non-placed state and process result data of the specimen input with said input unit and processed by the plasma process in the specimen placed state, and storing said prediction equation,
wherein said controller predicts the process result of a succeeding plasma process in accordance with plasma state data newly acquired via said state detector in the specimen non-placed state and said stored prediction equation.

2. The plasma processing apparatus according to claim 1, wherein said plasma process simulating a specimen existing state in said processing chamber is a plasma process to be performed by introducing into said processing chamber a process gas containing compositions of reaction byproducts to be obtained when said specimen is subjected to the plasma process.

3. The plasma processing apparatus according to claim 1, wherein said plasma process simulating a specimen existing state in said processing chamber is a process to be performed by introducing into said processing chamber a process gas containing at least one of SiF₄, SiCl₄ and SiBr₄.

4. The plasma processing chamber according to claim 1, further comprising means for heating or cooling said plasma processing chamber or means for generating an ion attracting electric field in said plasma processing chamber, respectively for a process in the specimen non-placed state.

5. The plasma processing apparatus according to claim 1, wherein the process in the specimen non-placed state is a process to be performed by introducing gas containing Br or Cl.

6. The plasma processing apparatus according to claim 1, wherein the process in the specimen non-placed state is a process to be performed by introducing gas for removing deposits in said processing chamber or gas for depositing deposits in said processing chamber.

7. The plasma processing apparatus according to claim 1, wherein the process in the specimen non-placed state is a process to be performed by introducing into said processing chamber gas containing at least ones of fluorine atoms, oxygen atoms, silicon atoms and carbon atoms.

8. The plasma processing apparatus according to claim 1, wherein the plasma state data detected with said state detector in the plasma process in the specimen non-placed state is data acquired immediately before completion of said plasma process.

9. The plasma processing apparatus according to claim 1, wherein prediction of the process result is made in real time.

10. A plasma processing apparatus comprising:
a processing chamber for executing a plasma process by generating plasma in a specimen placed state and in a specimen non-placed state, said processing chamber including process gas supply means and plasma generator means;
state detector means for detecting a state of plasma in said processing chamber;
input means for inputting process result data of a specimen processed in said plasma processing chamber; and
a controller including prediction equation forming means for forming a prediction equation of a process result in accordance with plasma state data detected with said state detector means for the plasma process in the specimen non-placed state and process result data of the specimen input with said input means and processed by the plasma process in the specimen placed state,
wherein said controller predicts the process result of a succeeding plasma process in accordance with plasma state data newly acquired via said state detector means in the specimen non-placed state and said prediction equation.

11. The plasma processing chamber according to claim 10, further comprising means for heating or cooling said plasma processing chamber or means for generating an ion attracting electric field in said plasma processing chamber, respectively for a process in the specimen non-placed state.

12. The plasma processing apparatus according to claim 10, wherein the process in the specimen non-placed state is a process to be performed by introducing gas containing Br or Cl.

13. The plasma processing apparatus according to claim 10, wherein the process in the specimen non-placed state is a process to be performed by introducing gas for removing deposits in said processing chamber or gas for depositing deposits in said processing chamber.

14. The plasma processing apparatus according to claim 10, wherein the process in the specimen non-placed state is a process to be performed by introducing into said processing chamber gas containing at least ones of fluorine atoms, oxygen atoms, silicon atoms and carbon atoms.

15. The plasma processing apparatus according to claim 10, wherein the plasma state data detected with said state detector in the plasma process in the specimen non-placed state is data acquired immediately before completion of said plasma process.

16. The plasma processing apparatus according to claim 10, wherein prediction of the process result is made in real time.

17. A process result prediction method for a plasma processing apparatus including: a processing chamber which performs a plasma process by generating plasma in a specimen placed state and in a specimen non-placed state, said processing chamber including a process gas supplier and a plasma generator; a state detector which detects a state of plasma in said processing chamber; and an input unit which inputs process result data of a specimen processed in said plasma processing chamber, the method comprising steps of:
in performing the plasma process, simulating a specimen existing state in said processing chamber in the specimen non-placed state,
forming a prediction equation of a process result in accordance with plasma state data detected with said state detector and process result data of the specimen input with said input unit and processed by the plasma process in the specimen placed state; and
predicting the process result of a succeeding plasma process in accordance with said formed prediction equation and plasma state data newly acquired via said state detector in the specimen non-placed state.

18. The process result prediction method for a plasma processing apparatus according to claim 17, wherein said plasma process simulating a specimen existing state in said processing chamber is a plasma process to be performed by introducing into said processing chamber a process gas containing compositions of reaction byproducts to be obtained when said specimen is subjected to the plasma process.

19. The process result prediction method for a plasma processing apparatus according to claim 17, wherein said plasma process simulating a specimen existing state in said processing chamber is a plasma process to be performed by introducing into said processing chamber a process gas containing at least one of SiF₄, SiCl₄ and SiBr₄.
